(19) United States
(12) Patent Application Publication
(10) Pub. No.: US 2007/0226555 A1
(43) Pub. Date: Sep. 27, 2007

(54) Graphical presentation of semiconductor test results

(76) Inventor: Gary Raines, Jonestown, TX (US)

Correspondence Address: VERIGY, 4700 INNOVATION WAY, BLDG D1, FORT COLLINS, CO, 80528, US

(21) Appl. No.: 11/385,438

(22) Filed: Mar. 21, 2006

(51) Int. Cl. G01R 31/28

(52) U.S. Cl. 714/724

(57) ABSTRACT

Methods and apparatus for graphically presenting test results of a circuit device under test are presented. Test results of a circuit device under test are acquired. Graphical diagrams comprising representations of at least a portion of the circuit device under test and having circuit components and associated circuit component terminals are generated with test results for nodes of the circuit device under test mapped to circuit component terminals of the displayed diagrams.

### BACKGROUND OF THE INVENTION

The present invention relates generally to integrated circuit devices, and more particularly a novel technique for graphically displaying semiconductor test results to allow visualization of sources of faults.

Integrated circuit assemblies are ubiquitous in modern electronic devices, and a large portion of the industrial sector is devoted to the design and manufacture of such devices. As electronic devices are continually being improved and becoming more sophisticated, so are consumers' expectations for the level of quality of these products. Accordingly, new and improved testing techniques are continuously being sought by manufacturers to test the quality of integrated circuits, printed circuit boards, and integrated circuit assemblies after manufacture and prior to shipment of these devices. While testing entails checking many aspects of the product, such as functionality testing and burn-in testing, one of the most important tests after manufacture is basic continuity testing. Continuity testing may include two aspects: opens testing and shorts testing. Opens testing is performed to ensure that all connections that are supposed to be connected between components of the device (e.g., integrated circuit pins to printed circuit boards, integrated circuit lead wires to pins, traces connections between printed circuit board nodes, etc.) are intact. Shorts testing is performed to ensure that all connections on the device are connected only between nodes that they are intended by design to connect.

Integrated circuit devices such as integrated circuits, integrated circuit assemblies, printed circuit boards (PCBs), and printed circuit assemblies (PCAs) are typically tested using industrial in-circuit test (ICT) testers. ICT testers are generally equipped with an array of tester interface pins that are configurably connectable to various tester resources (e.g., current sources, voltage sources, measuring devices, etc.). An integrated circuit device may be mounted on a tester fixture that includes a number of probes that connect respective tester interface pins to corresponding respective nodes of the integrated circuit device.

As used herein, the term “node” refers to the conductive portion of an electrical device that forms a single electrical point in the equivalent schematic diagram of the electrical device. For example, a node can be a pad of an integrated circuit die, a pin, a wire, a solder bump, a pad, a trace, or other conductively interconnecting joint of a component of an integrated circuit device, or any combination thereof. As also used herein, the term “integrated circuit” and “integrated circuit device” may comprise an integrated circuit die, an integrated circuit package, an integrated circuit assembly, a printed circuit board (PCB), and/or a printed circuit assembly (PCA).

Integrated circuit devices comprise circuit components having one or more circuit terminals that are operatively interconnected. As used herein, a “component” is a circuit device implemented on the integrated circuit device that includes one or more input terminals that may receive one or more corresponding input signals and generates one or more output signals on one or more corresponding output terminals. As used herein a “terminal” is the port through which signals may be received by the component and through which signals may be output by the component. A terminal may include a pin, a pad, a lead, a wire, a bead, or any other port or combination thereof.

Connections between terminals of circuit components in the circuit are typically implemented by way of traces and vias. Routing of signals between terminals in a circuit may be quite complex. Accordingly, it may be quite difficult, and is rare, in fact, for an ICT tester to actually probe the terminal of a component directly. Instead, a circuit is designed with test contact points that are designed to be probed by the tester interface pins of a tester, or more typically by the probes of a tester fixture which interfaces between the tester interface pins and the test contact points of the integrated circuit device.

Tester interface pins map to test contact points on the integrated circuit device under test (DUT). When a test contact point is probed by a tester interface pin or interfacing test probe, the ICT tester becomes electrically conductive with the circuit. An ICT tester may apply a stimulating signal to a test contact point on a DUT, and a measurement may be made which may be used to determine whether or not a failure exists on a terminal connected to the node of the test contact point. For example, to test for continuity between a trace on a PCB of the DUT and a terminal of a component (i.e., to check that the component terminal is properly soldered to the trace), a test contact point connected to the trace may be stimulated and a signal may be measured at the component terminal by a capacitive sensing probe (for example, using a capacitive probe system as described in U.S. Pat. No. 5,498,964 to Kerschner et al, which is incorporated herein by reference for all that it teaches). The value of the measured signal indicates whether or not the component terminal is properly connected to the trace.

When an ICT tester is configured, a description of the circuit design of the DUT is downloaded to the tester. Each node must be uniquely identified, and any specific component terminals to be tested must also be uniquely identified. Test results are collected on a per node-terminal basis rather than merely a per-node basis because more than one terminal is typically connected to any given node. For example, consider a trace connecting two component terminals—whereas the trace and the two terminals are together considered as a single “node” for purposes of the schematic diagram, the two terminals must be considered independently for purposes of testing connectivity between the respective terminals and the trace. Thus, test results are returned on a per-terminal basis rather than a per-node basis.

In large complex integrated circuit devices, the relationship of a failed terminal to the overall integrated circuit device design may not be immediately obvious due to the different naming conventions between the respective package terminal (as defined as a single instance of the component in the data sheet corresponding to the component) and the name of the terminal as defined in the corresponding DUT schematic. Furthermore, for any given component, there is often no physical way to see which component input terminals are related to which component output terminal. To understand this, the engineer must typically refer to a data sheet provided by the manufacturer of the component that contains the component specifications and often block diagrams of the internal circuitry of the component which allows the engineer to see which inputs are related to which outputs and how. However, there is no existing circuit test results analysis system that links the component data sheets to the nodes of an integrated circuit device under test. Accordingly, once the failure information has been collected upon performing a series of ICT tests, it may still be difficult to quickly ascertain source(s) of the failures.

### SUMMARY OF THE INVENTION

Embodiments of the invention includes methods and apparatus for graphically presenting test results of a circuit device under test.

In one embodiment, a method for graphically presenting test results of a circuit device under test includes acquiring test results for corresponding circuit device nodes of the circuit device under test, accessing a graphical diagram comprising a representation of at least a portion of the circuit device under test, the representation comprising a circuit component and associated circuit component terminals, mapping the circuit component terminals represented in the graphical diagram to corresponding circuit device nodes of the circuit device under test, and displaying the graphical diagram, enabling display of the test results corresponding to the circuit device nodes mapped to the circuit component terminals represented in the graphical diagram.

In one embodiment, the method is implemented as program instructions tangibly embodied on a computer readable storage medium.

In one embodiment, a circuit test results analysis system includes test results receiving means for receiving test results for corresponding circuit device nodes of a circuit device under test, and graphical diagram generation means for accessing a graphical diagram comprising a representation of at least a portion of the circuit device under test, the representation comprising a circuit component and associated circuit component terminals, mapping the circuit component terminals represented in the graphical diagram to corresponding circuit device nodes of the circuit device under test, and displaying the graphical diagram, enabling display of the test results corresponding to the circuit device nodes mapped to the circuit component terminals represented in the graphical diagram.

### BRIEF DESCRIPTION OF THE DRAWINGS

A more complete appreciation of this invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a block diagram of a circuit testing process that incorporates an embodiment of a circuit test results analysis system;

FIG. 2 is a block diagram of one embodiment of the circuit test results analysis system;

FIG. 3 is a high-level flowchart for one embodiment of software which implements the functions of the circuit test results analysis program;

FIG. 4 is a block diagram of a circuit under test;

FIG. 5 is a block diagram of a component of the circuit under test;

FIG. 6 is a block diagram of a component of the component shown in FIG. 5;

FIG. 7 is a block diagram of a circuit test results analysis system illustrating a functional diagram of one embodiment of a circuit test results analysis program;

FIG. 8 is an embodiment of an example display screen that may be generated by an embodiment of a circuit test results analysis program;

FIG. 9 is an embodiment of an example display screen that may be generated by an embodiment of a circuit test results analysis program that displays an example package diagram;

FIG. 10 is an embodiment of an example display screen that may be generated by an embodiment of a circuit test results analysis program that displays an alternative example package diagram;

FIG. 11 is an embodiment of an example display screen that may be generated by an embodiment of a circuit test results analysis program that displays an example circuit diagram;

FIG. 12 is an embodiment of an example display screen that may be generated by an embodiment of a circuit test results analysis program that displays an example circuit diagram illustrating more detail of a selected component;

FIG. 13 is an embodiment of an example display screen that may be generated by an embodiment of a circuit test results analysis program that displays an example setup dialog;

FIG. 14 is an embodiment of an example display screen that may be generated by an embodiment of a circuit test results analysis program that displays an example timing setup dialog;

FIG. 15 is a flowchart illustrating an exemplary method for mapping DUT node names to diagram nodes names; and

FIG. 16 is a flowchart illustrating an exemplary method for mapping test results to diagram nodes.

### DETAILED DESCRIPTION

In the following detailed description of the embodiments, reference is made to the accompanying drawings which form a part hereof, and in which is shown by way of illustration specific embodiments in which the invention may be practiced. These embodiments are described in sufficient detail to enable those skilled in the art to practice the invention, and it is to be understood that other embodiments may be utilized and that structural logical and electrical changes may be made without departing from the spirit and scope of the present inventions. The following detailed description is, therefore, not to be taken in a limiting sense, and the scope of the present inventions is defined only by the appended claims.

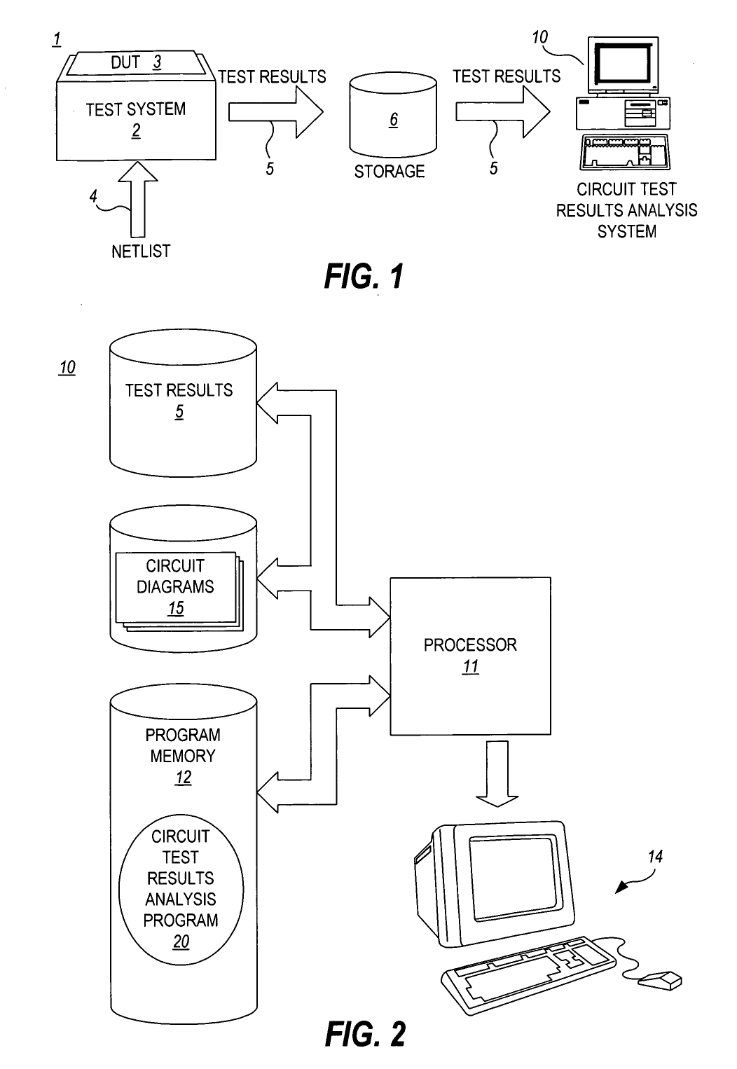

FIG. 1 shows components of a circuit testing process that incorporates an embodiment of a circuit test results analysis system 10. A circuit test system 2 receives a circuit design, hereinafter referred to as a “netlist” 4, which is used to configure the circuit test system 2 to run tests on an integrated circuit device implemented according to the circuit design defined by the netlist 4.

The circuit test system 2 receives an integrated circuit device (also referred to herein as a “device under test” or “DUT”) 3 implemented according to the circuit design defined by the netlist 4 and which is presented to the circuit test system 2 for testing.

The circuit test system 2 may be configured to run a number of tests on the DUT 3. Tests may include, by way of example only and not limitation, connectivity tests, functional tests, etc. During a test, one or more signals are applied to nodes of the DUT 3 and corresponding measurements may be made. Test results 5 are generated by the circuit test system 2. In one embodiment, the test results 5 are generated on a per-component-terminal basis. In other words, each component terminal that is stimulated and a corresponding measurement made that is associated with that terminal results in a test result 5 corresponding to that component terminal that comprises or is derived from the corresponding measurement. One or more tests may be executed that result in more than one test result 5 for a given component terminal.

In one embodiment, test results 5 may be stored in storage 6, such as a computer memory which may include computer memory in the form of registers, RAM, local disks, or external storage, to name only a few possibilities.

A circuit test results analysis system 10 receives test results 5. In one embodiment, the circuit test results analysis system 10 reads test results 5 from storage 6. In another embodiment, the circuit test results analysis system 10 receives test results 5 directly from the circuit test system 2.

FIG. 2 is a block diagram of one embodiment of the circuit test results analysis system 10 illustrating the major components of the system and logical connections therebetween. The circuit test results analysis system 10 includes a processor 11, which may be implemented as a computer, a microprocessor, a microcontroller, a programmable logic array (PLA), or any other computing device that performs the functions described herein of the processor 11. In one embodiment, the processor operates to read program instructions of a circuit test results analysis program 20 stored in program memory 12. In another embodiment, the program instructions of the circuit test results analysis program 20 are embedded or encoded in the processor device itself, for example in the case that the processor 11 is implemented using a PLA. The processor 11 performs the functionality of the circuit test results analysis program 20, described in more detail hereinafter.

The circuit test results analysis program 20 requires access to test results 5 and to one or more circuit diagrams 15. The test results 5 and circuit diagrams 15 may be stored for access by the processor 11 in a computer-readable data memory, which may be implemented as any combination of random access memory (RAM), read-only memory (ROM), local cache memory, local hard-drive memory, and/or long-term storage memory, or any variation thereof.

The processor 11 also performs, directly or indirectly, the functionality required for interfacing with the input and output devices of the circuit test results analysis system 10. Input devices of the system 10 include means to receive user input, which may take the form of any combination of a keyboard, a mouse, a infrared (IR) device, a touchscreen, a microphone which may interface with voice-recognition software, an external media drive which reads media, or any other device from which user input may be received. Output devices of the system 10 include means to present circuit test results analysis program output to the user, which may take the form of any combination of a display, a touchscreen, a printer, or any other device to which display output may be displayed.

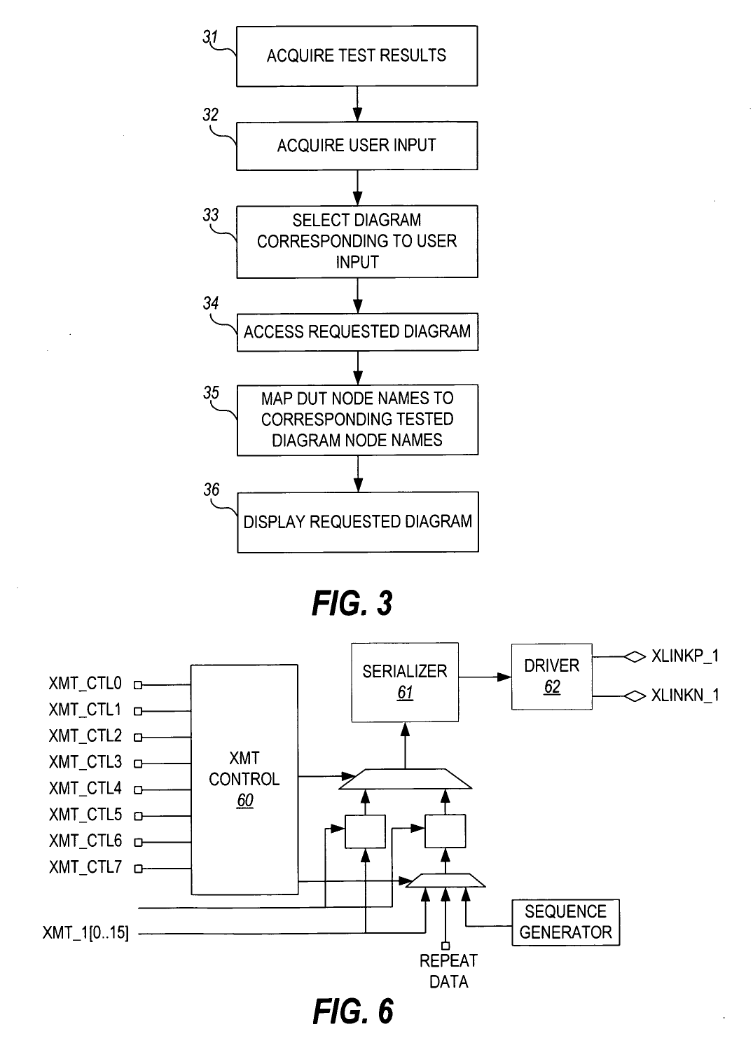

FIG. 3 is a high-level flowchart for one embodiment of software which implements the functions of the circuit test results analysis program 20. The software acquires test results corresponding to a particular DUT at block 31. The test results include what shall hereinafter be referred to as “DUT node names” and corresponding test result information. DUT node names are the names of corresponding nodes on the DUT as known by the circuit test system. Thus, the DUT node names are typically node names defined in the netlist used to configure the circuit test system. The corresponding test result information is information regarding how the corresponding node performed in a given test. The corresponding test result information may therefore be in the form of a pass or fail indication, a number of failures, a measured parameter value, etc.

The software acquires user input in block 32. The software processes the user input to select a diagram that meets the criteria of the user input in block 33.

The software accesses the requested diagram from a pool of diagrams corresponding to the requested diagram in block 34. The requested diagram may take the form of a block diagram, a schematic, or a circuit package. Each diagram includes what shall hereinafter be referred to as “tested diagram nodes”. Tested diagram nodes are nodes of a diagram having corresponding DUT nodes for which test results have been received (in block 31).

In one embodiment, the DUT node names of the DUT nodes and the tested diagram node names of the tested diagram nodes corresponding to the respective DUT nodes may have different names. In a given netlist, each circuit component is assigned a unique device name. Since there may be multiple instances of any given component, there may also be multiple instances of the terminals of the given component, resulting in multiple identical terminal names in the circuit. Accordingly, each terminal in the DUT schematic may be assigned a unique name. In one embodiment, a terminal is referred to by the combination of the terminal name and the unique device name of the corresponding component.

The software maps DUT node names to corresponding tested diagram node names in block 35. The software displays the requested diagram in block 36. The software then awaits user input again in block 32.

Test result information of tested diagram nodes may be displayed directly in the displayed diagram. In one embodiment, the diagram displays a number of failures detected on respective tested nodes in the form of a chart. For example, in one embodiment, the number of failures of the respective tested nodes is displayed in the form of a histogram or bargraph, comprising a bar having a length which corresponds to a number of failures detected on the respective node. In one embodiment, the number of failures of the respective tested nodes is displayed in the form of a color wherein different colors correspond to different numbers of failures.

In one embodiment, the software displays indication of available expansion of one or more components and/or nodes of the displayed circuit for which there exists more displayable information. In one embodiment, the expansion indicator comprises a hyperlink. In other embodiments, the expansion indicator may be a drop-down list, a button, etc.

The user input may comprise a selection of an expandable component or node displayed in the diagram as selected by the user. In this embodiment, the software selects a next diagram from a pool of diagrams corresponding to the selected component or node. As with all diagrams, nodes of the next diagram having corresponding test results are mapped and then displayed. Typically, the next diagram comprises a finer level of detail than the previous diagram. For example, the next diagram may comprise a subcircuit of the circuit displayed in the previous diagram, and may include more detail including components and/or nodes not displayed in the previous diagram. Available test results corresponding to respective nodes in the next diagram may be viewed.

In one embodiment, the circuit diagrams comprise block diagrams and/or schematic diagrams available from published data sheets corresponding to the respective circuit. The DUT node names are mapped to the corresponding tested diagram node names, which are the terminal names of the component as published in the data sheets corresponding to the component.

As previously described, integrated circuit devices are typically tested using ICT testers. An integrated circuit device comprises a number of interconnected electronic components. Each component typically has at least one input terminal and at least one output terminal. Input terminals may be connected to receive a power signal, a ground, or an input signal. Output terminals may be connected to output an output signal to other portions of the circuit. Input and output terminals may be implemented as a pin, a lead, a wire, a pad, etc.

In order to test a given integrated circuit device, the tester must be configured to understand what nodes on the device will be probed and to which component terminals those nodes should be connected. An ICT tester is typically configured by, among other actions, downloading a netlist of the circuit of the integrated circuit device to the tester. A netlist is typically a text description of the circuit connectivity, and includes a list of connectors, a list of component instances, and, for each component instance, a list of the signals connected to the component instance terminals. There may be more than one instance of a particular component. All instances of a particular component are identical, having identical internal circuitry and the same number and names of terminals. The package layout including terminal names (also referred to as “pin-out”) and operation of a particular component may be defined in a corresponding datasheet provided by the manufacturer of the component. All instances of a particular component therefore may therefore be understood by referral to a single datasheet.

Naming conventions of a custom designed circuit may differ from the naming conventions used in the corresponding data sheets of pre-manufactured components used in the integrated circuit device design. Thus, it may be difficult to understand the location and cause of a failure, and how to repair the failure, based only upon the DUT node names of failing DUT nodes that are returned with the test results from the ICT tester.

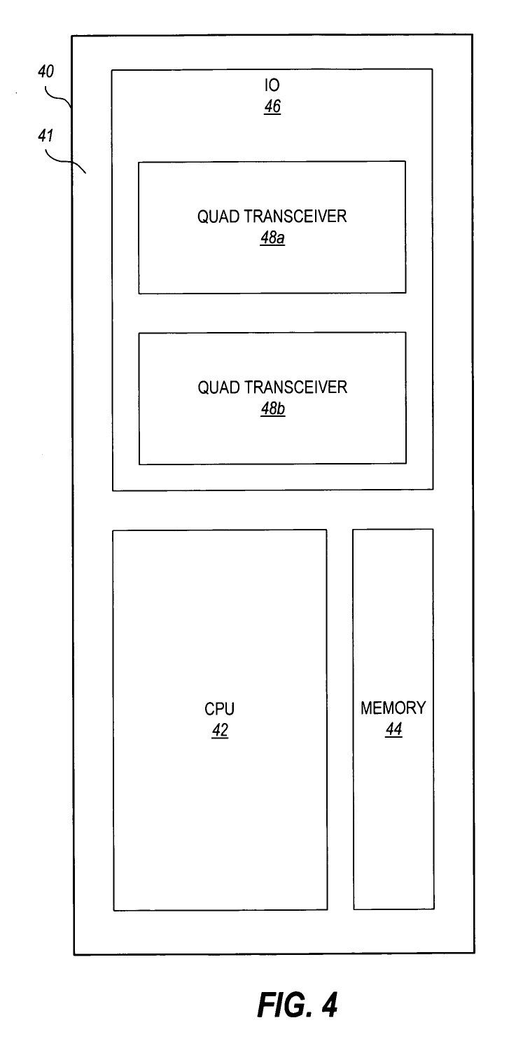

For example, consider the block diagram of a circuit 40 (embodying a quad transceiver) mounted on a PCB 41, as shown in FIG. 4. The circuit 40 at the block diagram level includes a CPU block 42, a memory block 44, and an input/output (IO) block 46, connected in an operational manner. Many of the components of the circuit may be implemented using standard off-the-shelf components whose operation may be well-understood by referring to data sheets provided by the respective component manufacturers. For example, suppose that the IO block 46 includes a pair of quad transceivers 48a, 48b packaged and mounted on the PCB 41. Suppose further that the specifications of the quad transceivers 48a, 48b are provided (typically by the manufacturer) in a corresponding data sheet that includes a pin-out of the package and block diagrams and/or schematic diagrams of the internal operation of the transceiver circuitry. The data sheet typically also contains specifications such as maximum and minimum voltage levels, maximum and minimum temperatures, etc., and timing diagrams which illustrate the relationships between the input signals received at the input terminals of the transceiver and output signals output onto the output terminals of the transceiver. The data sheet of the chip will show the pin-out of the package, labeling each of the package terminals with corresponding names.

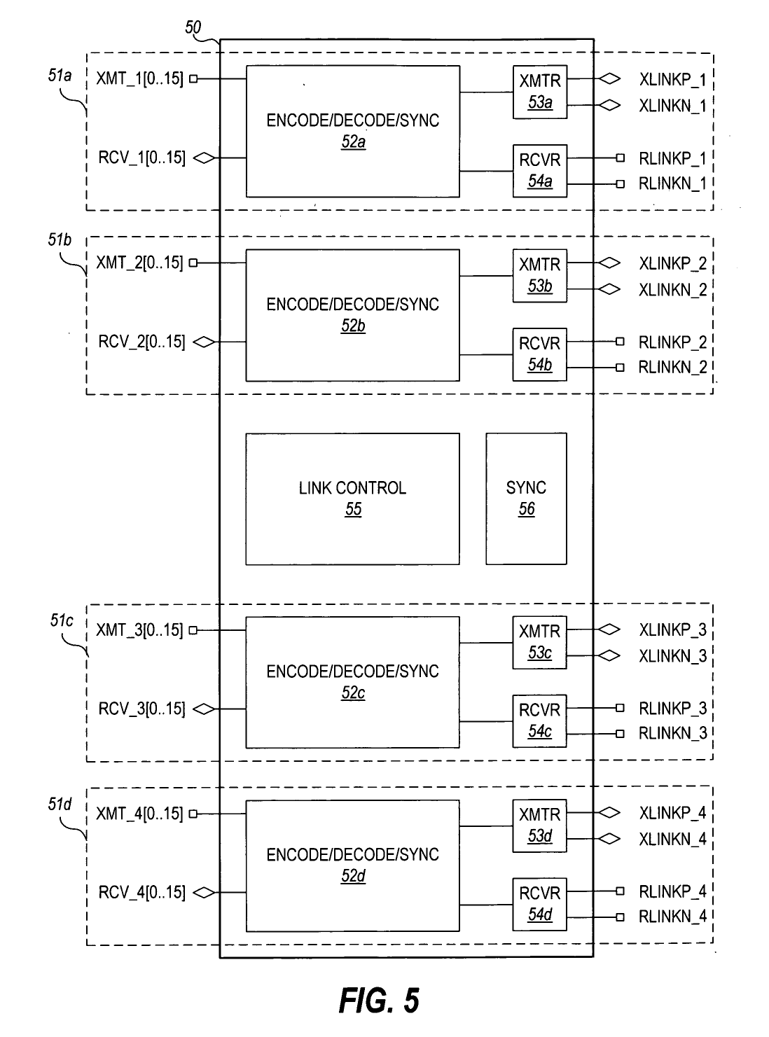

FIG. 5 is an example block diagram of a quad transceiver 50 in the form of a combination package layout diagram and block diagram that may be presented in a data sheet corresponding to a particular transceiver chip implementing the transceiver 42. The transceiver 50 includes four single transceiver blocks 51a, 51b, 51c and 52d, a link control block 55, and a synchronization block 56. The input and output terminals shown in the block diagram corresponding to actual input and output terminals of an actual corresponding quad transceiver chip. The labels of the input and output terminals typically are at least somewhat descriptive of the signal(s) to be input or output on the corresponding terminal.

A data sheet of a pre-manufactured component such as an integrated circuit chip may include additional block diagrams of individual blocks within the main circuit. For example, the data sheet corresponding to the quad transceiver 50 may also include a schematic block diagram of an individual transmitter 53, illustrated in FIG. 6, implementing each of the transmitter blocks 53a, 53b, 53c, 53d within each of the corresponding transceiver blocks 51a, 51b, 51c, 51d. The block diagram 53 presents the circuitry of a transmitter block 53a, 53b, 53c, 53d in finer detail, which may be useful in debugging problems with the connections or setup of the circuit.

It will be appreciated that from the viewpoint of the tester, each node, terminal, and signal in a given DUT must have a unique name across the circuit in order for the ICT tester to uniquely test each node or terminal in the circuit. The same holds true from the viewpoint of the engineer debugging the circuit.

It will further be appreciated, however, that because each signal and node in a given circuit must be uniquely named for input to the ICT tester, it is rare that the names chosen for each of the nodes, components, and component terminals in the DUT (typically as defined in the netlist) actually match the corresponding names of the terminals as labeled in the manufacturer data sheets of the associated components. This problem is further exacerbated when more than one instance of a given component is used in the DUT circuit (leading to multiple components with identical sets of terminal names) and when one or more higher-level component is implemented using lower-level components from more than one different manufacturer (which may label the terminals of their manufactured chip using different names even though the functionality and pin-out is identical).

When test results are presented to the debug engineer, it is useful and therefore typical to present the results using the DUT node names—that is, the names of the nodes, terminals and signals of the schematic that the engineer is working with. As discussed previously, ICT test results may be returned on a per-terminal basis, comprising the name of a terminal and corresponding test result information. Accordingly, when a set of ICT test results are received, it may be very difficult and/or time-consuming for the debug engineer to determine and understand the relationship between the ICT test failures and the location of the failure within the circuit or how to modify the signals in the circuit to repair the circuit because of the different naming conventions of the components, nodes, terminals, and signals of the DUT as known by the ICT tester and the names of the terminals and signals as identified in the data sheets of pre-manufactured components used in the circuit.

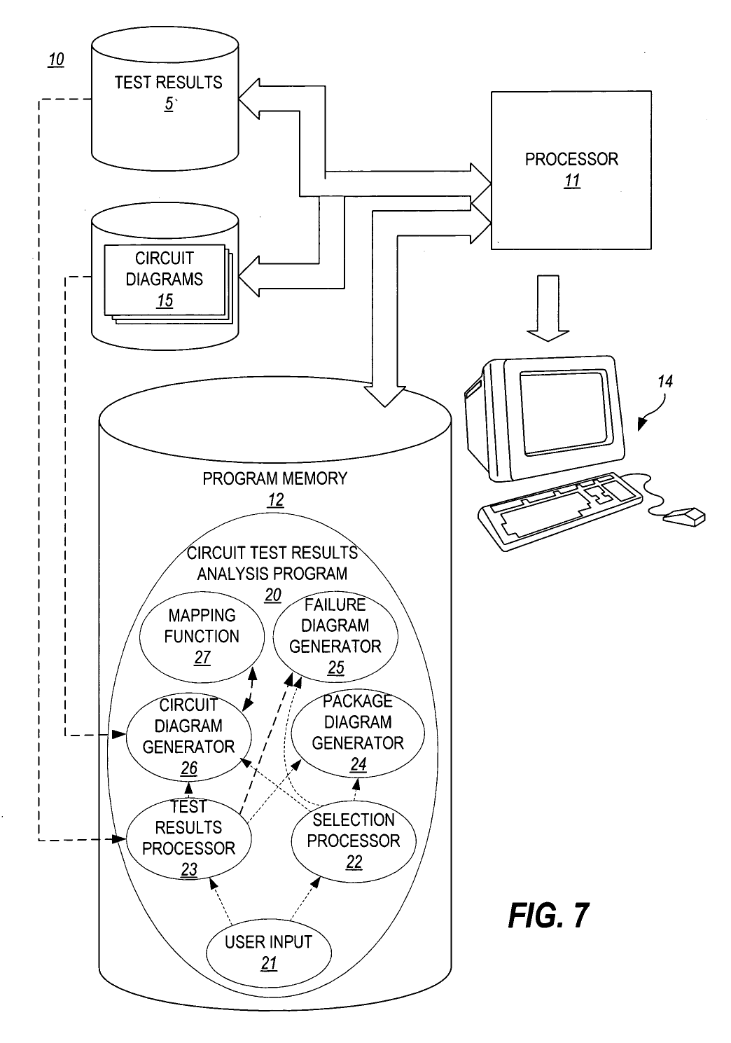

FIG. 7 is an embodiment of the circuit test results analysis system 10 illustrating a functional diagram of one embodiment of the circuit test results analysis program 20. In this embodiment, the circuit test results analysis program 20 includes a user input function 21 which monitors the input device(s) 14 for diagram selection input from the user and invokes a selection processor 22 upon receiving valid diagram selection input. The selection processor 22 invokes one of the diagram generator functions (for example, a package diagram generator 24, a failure diagram generator 25, or a circuit diagram generator 26) corresponding to the diagram selection input. The diagram generators 24, 25, 26 retrieve a corresponding diagram 15. The corresponding diagram will have a number of nodes, components, terminals, and/or signals that will be displayed and which will have corresponding test results that correspond to those nodes, components, terminals, and/or signals. A test results processor 23 retrieves test results 5 corresponding to the diagram nodes, components, terminals and/or signals. A mapping function 25 maps DUT design names to diagram names, or vice versa. The active diagram generator 24, 25, 26 displays the selected diagram on the output means (i.e., display) 14. If test results are available for a node, a terminal, a component or a signal displayed in the diagram, the test results are made available either directly (via visual indication on the display) or indirectly (via an expansion mechanism such as a hyperlink, a menu, etc.).

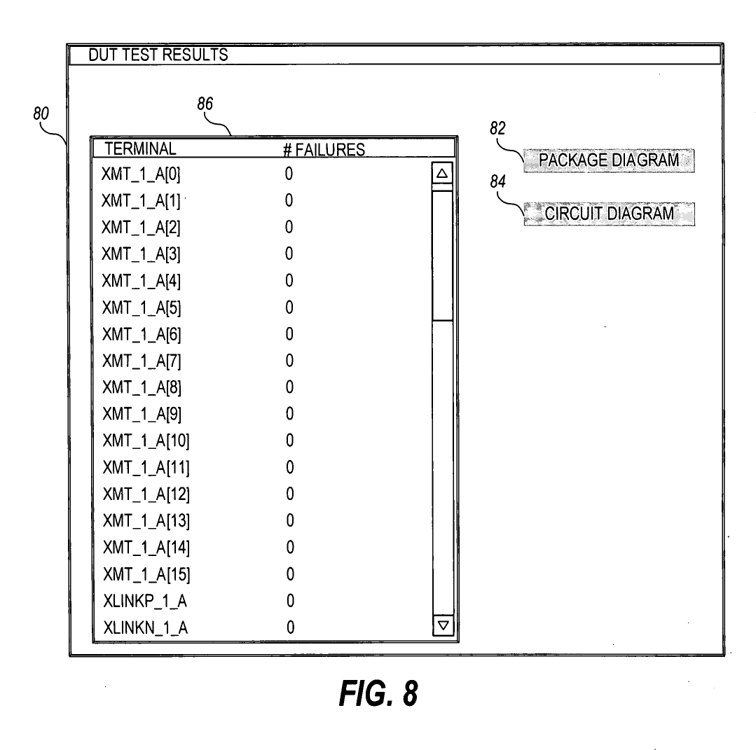

Turning now to an example, consider the use of the circuit test results analysis system 10 for examining test results of the quad transceiver 50 of FIG. 5. FIG. 8 is an embodiment of an example display screen that may be generated by an embodiment of a circuit test results analysis program 20. The screen 80 may provide links for displaying test result information. For example, the screen 80 may provide a hyperlink 82 to allow display of a package diagram of the DUT. The screen 80 may provide a hyperlink 84 to allow display of a circuit diagram of the DUT. The screen 80 may display (as shown at 86), or provide a hyperlink (not shown) to display, the actual test results themselves. The diagrams may be accessed using any one or more of well-known graphical user interface or web page traversal navigation mechanisms, including hyperlinks, menus, toolbars, etc.

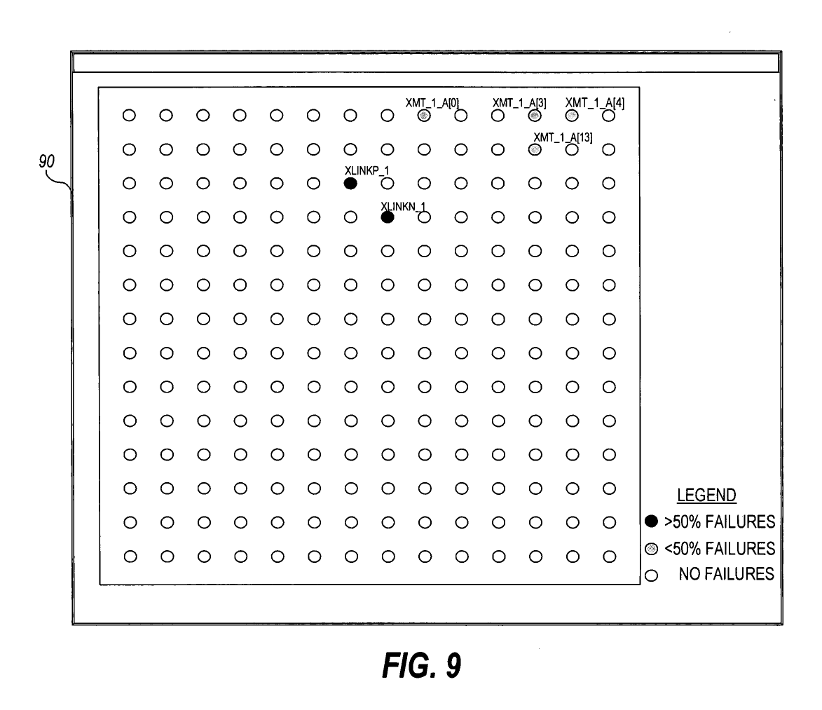

FIG. 9 is an example package diagram 90 that may be displayed upon selection of the package diagram hyperlink 82 from the screen 80 of FIG. 8. As illustrated, the package diagram 90 includes a representation 92 of the selected component package. The component package representation 92 includes representations of the component package input and output terminals, and corresponding test result information for those terminals for which corresponding test results are available. The package diagram 90 may be useful, for example, to immediately ascertain which terminals have a connectivity problem. The test result information may be presented, in one embodiment, using different colors corresponding to different numbers of failures. For example, suppose the ICT tester runs a series of ten tests on a DUT. The test results may be accumulated for each terminal of the package and presented directly on the package diagram by designating different colors to different ranges of numbers of failures. Thus, as shown in FIG. 9, terminals XLINKP_1_A and XLINKN_1_A each have greater than 50% failures, terminals XMT_1_A[0], XMT_1_A[3], XMT_1_A[4], and XMT_1_A[13] each have greater than 50% failures, and the remaining terminals have no failures.

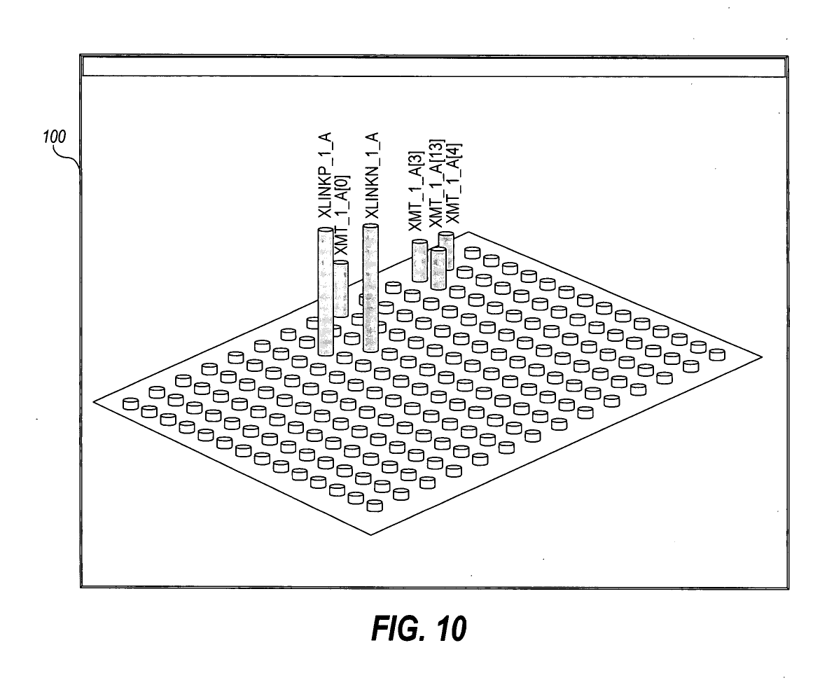

FIG. 10 is an alternative example package diagram 100 that may be displayed upon selection of the package diagram hyperlink 82 from the screen 80 of FIG. 8. As illustrated, the package diagram 100 includes a representation 102 of the selected component package. The component package representation 102 includes representations of the component package input and output terminals, with corresponding terminal labels and corresponding test result information for those terminals for which corresponding test results are available. The test result information is presented in this embodiment using a bar graph. The view of the package is rotated and a bar graph is displayed on each terminal. The length of the bar indicates the number of failures detected on the corresponding terminal. Again, as shown in FIG. 10, terminals XLINKP_1_A and XLINKN_1_A each have greater than 50% failures, terminals XMT_1_A[0], XMT_1_A[3], XMT_1_A[4], and XMT_1_A[13] each have greater than 50% failures, and the remaining terminals have no failures.

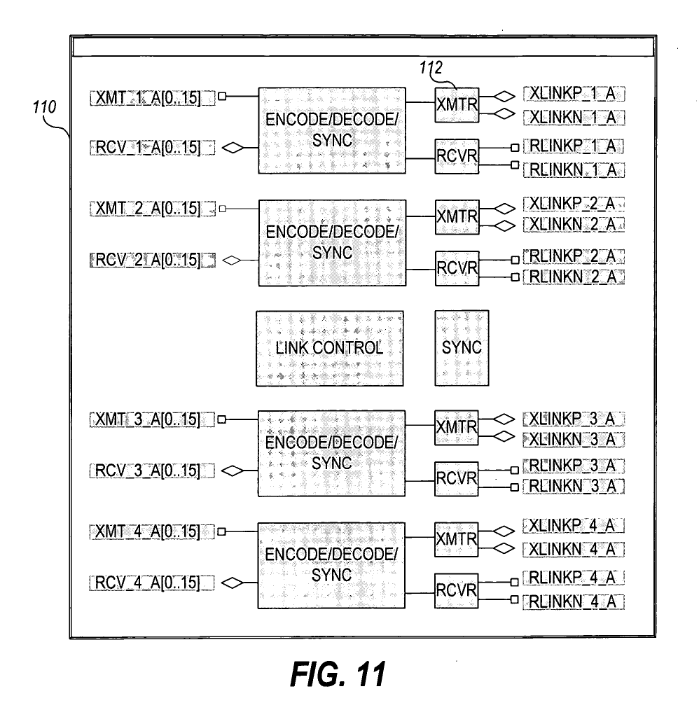

FIG. 11 is an example circuit diagram 110 that may be displayed upon selection of the circuit diagram hyperlink 84 from the screen 80 of FIG. 8. The circuit diagram 110 illustrates the functional circuit of the component. The circuit diagram 110 may display the functional circuit of the component in the form of a block diagram, a schematic block diagram, or a schematic diagram. The component package input and output terminals are represented, along with directly or indirectly accessible corresponding test result information. For example, test result information corresponding to a particular terminal displayed in the circuit diagram 110 may be displayed directly in the diagram itself through the use of different colors indicating different test results, a bar graph display directly on the terminal, etc. Alternatively, as indicated by shading in FIG. 10, terminals with associated test result information may be selectable (i.e., through a hyperlink, a menu item, a toolbar item, etc.) so that when selected by the user, the test results are displayed in another window or screen.

Components displayed in the circuit diagram 110 may also be made selectable (again indicated by shading) to view a finer detail diagram of the selectable component. By being able to understand which input terminals have failures, and which output terminals are affected by those input terminals, the user may more easily understand the cause of the failure and potential fixes to repair the failures relative to the component being viewed.

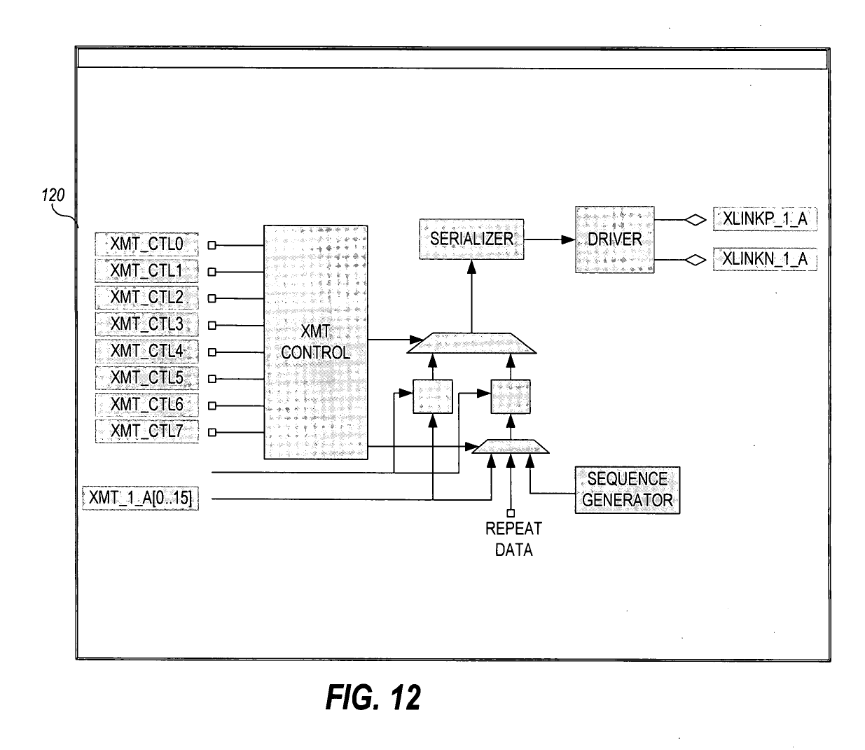

For example, transmitter block 112 in FIG. 11 may be selectable to view the internal functionality of the transmitter. FIG. 12 illustrates an example circuit diagram 120 that may be displayed upon selection of the transmitter block 112 in FIG. 11. Terminals may be further selectable, as indicated in FIG. 11 by shading, to display additional diagrams, associated test information, and/or setup dialogs.

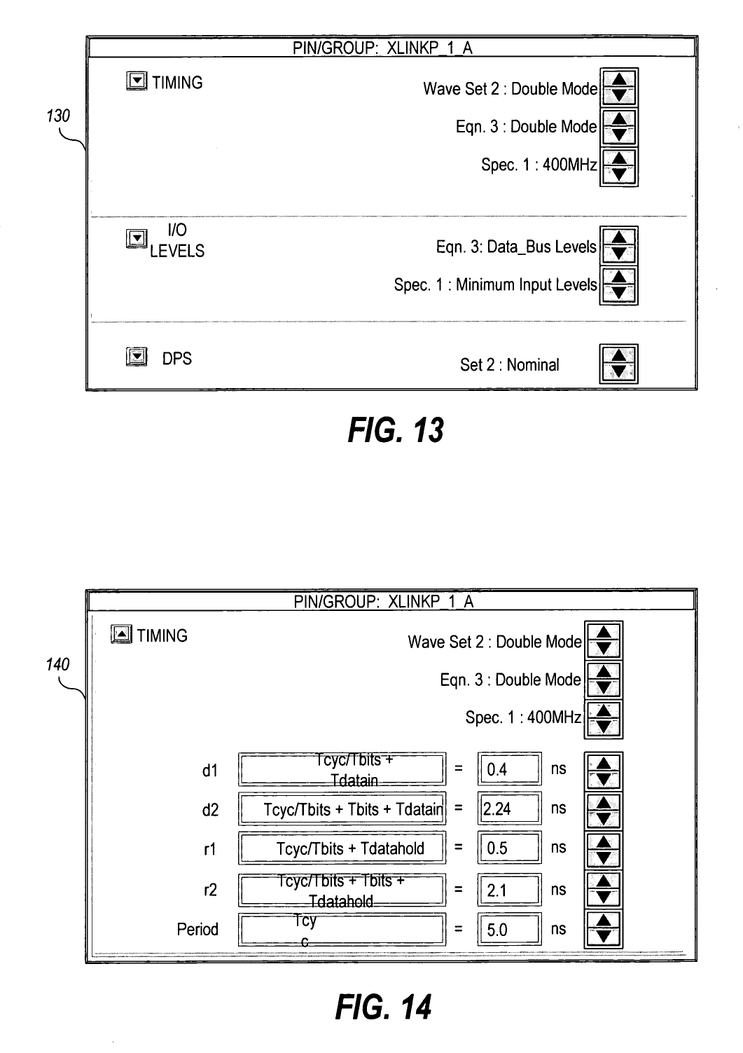

For example, the terminal XLINKP_1_A may be selected to bring up a setup dialog as shown in the example screen 130 in FIG. 13. The setup dialog may allow parameters associated with the terminal or signal applied to the terminal to be set up by the user. For example, timing parameters may be selected to bring up a timing setup dialog, as illustrated in the example screen 140 shown in FIG. 14. Timing and other setup parameters may be adjusted, which, depending on the types of tests and test failures, may fix or assist in debugging problems with the DUT under consideration.

The component terminal names in the displayed diagrams may be displayed as either the DUT node names or as the names utilized in the component data sheet, as long as the test results are mapped to the appropriate terminals in the displayed diagrams. The example screen diagrams shown in FIGS. 8-14 display the component terminal names with the corresponding DUT node names. The choice of whether to display the DUT node names or the component terminal names as shown in the data sheets depends on preferences associated with the particular implementation of the circuit test results analysis system. Alternatively, the circuit test results analysis system may allow the user to actively choose how to display the terminal names, for example through an options setup menu.

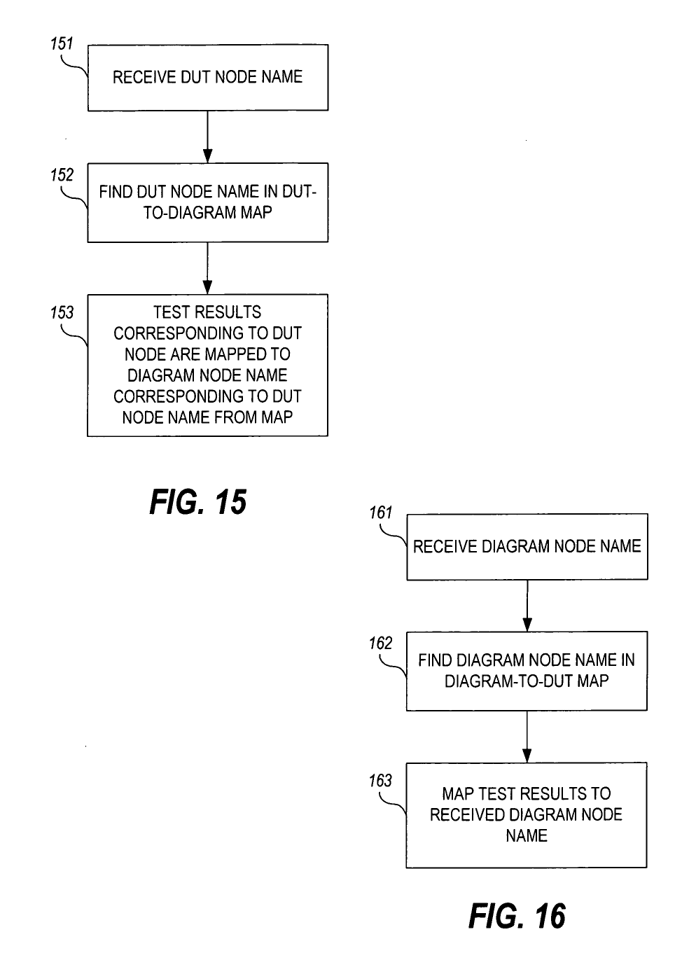

FIG. 15 is a flowchart illustrating a method for mapping DUT node names (including DUT terminal names) to diagram terminals names. A DUT node name is received in block 151. The received DUT node name is located in a DUT-to-diagram map in block 152. The test results corresponding to the DUT node identified by the received DUT node name are mapped to the diagram node name corresponding to received DUT node name looked up in the map in block 153.

FIG. 16 is a flowchart illustrating a method for mapping test results to diagram terminals names. A diagram terminal name is received in block 161. The received diagram terminal name is located in a diagram-to-DUT map in block 162. The test results corresponding to the DUT node identified in the map corresponding to the received diagram node name are mapped to the received diagram node name in block 163.

In summary, test results output by an ICT tester may be presented in a useful format tied directly to graphical diagrams of the circuit under test with links to diagrams illustrating the circuit functionality of components of the circuit and test result information associated with terminals of the components. Linking test result information to graphical diagrams of circuit functionality of components of the circuit allow efficient understanding by the user of which component terminals are related to which output terminals. Linking a setup dialog to the diagrams allows faster and more efficient debug and failure analysis.

Those of skill in the art will appreciate that the methods and apparatuses described and illustrated herein may be implemented in software, firmware or hardware, or any suitable combination thereof. The method and apparatus of the invention may be implemented by a computer or microprocessor process in which instructions are executed, the instructions being stored for execution on a computer-readable medium and being executed by any suitable instruction processor. Alternative embodiments are contemplated, however, and are within the spirit and scope of the invention.

Although this preferred embodiment of the present invention has been disclosed for illustrative purposes, those skilled in the art will appreciate that various modifications, additions and substitutions are possible, without departing from the scope and spirit of the invention as disclosed in the accompanying claims.

What is claimed is:

1. A method for graphically presenting test results of a circuit device under test, the method comprising:
acquiring test results for corresponding circuit device nodes of the circuit device under test;
accessing a graphical diagram comprising a representation of at least a portion of the circuit device under test, the representation comprising a circuit component and associated circuit component terminals;
mapping the circuit component terminals represented in the graphical diagram to corresponding circuit device nodes of the circuit device under test; and
displaying the graphical diagram, enabling display of the test results corresponding to the circuit device nodes mapped to the circuit component terminals represented in the graphical diagram.

2. The method of claim 1, wherein the test results corresponding to the circuit device nodes mapped to the circuit component terminals represented in the graphical diagram are displayed in the representation of the circuit component and associated circuit component terminals.

3. The method of claim 1, wherein the step for displaying the graphical diagram comprises displaying for each respective circuit component terminal a bargraph representing the test results corresponding to the circuit device node that is mapped to the respective circuit component terminal.

4. The method of claim 1, wherein the step for displaying the graphical diagram comprises displaying for each respective circuit component terminal a color representing a number of failures detected on the corresponding circuit device node that is mapped to the respective circuit component terminal.

5. The method of claim 1, wherein the graphical diagram comprises a package layout representation of the component.

6. The method of claim 5, wherein the package layout representation comprises a bargraph representing the test results corresponding to the circuit device node that is mapped to the respective circuit component terminal.

7. The method of claim 1, wherein the step for enabling display of the test results corresponding to the circuit device nodes mapped to the circuit component terminals represented in the graphical diagram comprises providing a selection mechanism associated with the circuit component terminal represented in the graphical diagram that, when selected, display the test results corresponding to the circuit device node mapped to the selected circuit component terminal.

8. The method of claim 1, wherein the step for displaying the graphical image comprises providing a selection mechanism associated with the circuit component represented in the graphical diagram that, when selected, displays a functional diagram of the selected circuit component.

9. A computer readable storage medium tangibly embodying program instructions implementing a method for graphically presenting test results of a circuit device under test, the method comprising:
acquiring test results for corresponding circuit device nodes of the circuit device under test;
accessing a graphical diagram comprising a representation of at least a portion of the circuit device under test, the representation comprising a circuit component and associated circuit component terminals;
mapping the circuit component terminals represented in the graphical diagram to corresponding circuit device nodes of the circuit device under test; and
displaying the graphical diagram, enabling display of the test results corresponding to the circuit device nodes mapped to the circuit component terminals represented in the graphical diagram.

10. The computer readable storage medium of claim 9, wherein the test results corresponding to the circuit device nodes mapped to the circuit component terminals represented in the graphical diagram are displayed in the representation of the circuit component and associated circuit component terminals.

11. The computer readable storage medium of claim 9, wherein the step for displaying the graphical diagram comprises displaying for each respective circuit component terminal a bargraph representing the test results corresponding to the circuit device node that is mapped to the respective circuit component terminal.

12. The computer readable storage medium of claim 9, wherein the step for displaying the graphical diagram comprises displaying for each respective circuit component terminal a color representing a number of failures detected on the corresponding circuit device node that is mapped to the respective circuit component terminal.

13. The computer readable storage medium of claim 9, wherein the graphical diagram comprises a package layout representation of the component.

14. The computer readable storage medium of claim 13, wherein the package layout representation comprises a bargraph representing the test results corresponding to the circuit device node that is mapped to the respective circuit component terminal.

15. The computer readable storage medium of claim 9, wherein the step for enabling display of the test results corresponding to the circuit device nodes mapped to the circuit component terminals represented in the graphical diagram comprises providing a selection mechanism associated with the circuit component terminal represented in the graphical diagram that, when selected, display the test results corresponding to the circuit device node mapped to the selected circuit component terminal.

16. The computer readable storage medium of claim 9, wherein the step for displaying the graphical image comprises providing a selection mechanism associated with the circuit component represented in the graphical diagram that, when selected, displays a functional diagram of the selected circuit component.

17. A circuit test results analysis system, comprising:
test results receiving means for receiving test results for corresponding circuit device nodes of a circuit device under test;
graphical diagram generation means for accessing a graphical diagram comprising a representation of at least a portion of the circuit device under test, the representation comprising a circuit component and associated circuit component terminals, mapping the circuit component terminals represented in the graphical diagram to corresponding circuit device nodes of the circuit device under test, and displaying the graphical diagram, enabling display of the test results corresponding to the circuit device nodes mapped to the circuit component terminals represented in the graphical diagram.

18. The system of claim 17, wherein graphical diagram generation means displays the test results corresponding to the circuit device nodes mapped to the circuit component terminals represented in the graphical diagram.

19. The system of claim 17, wherein graphical diagram generation means generates and displays, for each respective circuit component terminal, a bargraph representing the test results corresponding to the circuit device node that is mapped to the respective circuit component terminal.

20. The system of claim 17, wherein graphical diagram generation means generates and displays, for each respective circuit component and respective circuit component terminal having available expanded information, a selection mechanism associated with the respective circuit component and respective circuit component terminal represented in the graphical diagram that, when selected, displays the available expanded information corresponding to the respective circuit component or respective circuit component terminal.
